(19) United States
(12) Patent Application Publication
(10) Pub. No.: US 2025/0040322 A1
(43) Pub. Date: Jan. 30, 2025

(54) METHOD OF MANUFACTURING OPTICAL MEMBER, AND LIGHT EMITTING DEVICE

(71) Applicant: NICHIA CORPORATION, Anan-shi (JP)

(72) Inventors: Mitsuo HAMADA, Komatsushima-shi (JP); Hiroaki TAMEMOTO, Anan-shi (JP); Minoru YAMAMOTO, Anan-shi (JP); Ryota TAOKA, Komatsushima-shi (JP); Kenta NISHIHARA, Tokushima-shi (JP)

(73) Assignee: NICHIA CORPORATION, Anan-shi (JP)

(21) Appl. No.: 18/780,099

(22) Filed: Jul. 22, 2024

(30) Foreign Application Priority Data
Jul. 26, 2023 (JP) 2023-121810
Mar. 7, 2024 (JP) 2024-034603

(51) Int. Cl. H01L 33/58

(52) U.S. Cl. CPC H01L 33/58

(57) ABSTRACT

A method of manufacturing an optical member includes: providing a polycrystalline wavelength conversion member including phosphor particles and having a first surface and a second surface opposite to the first surface; forming a modified portion inside the wavelength conversion member by focusing laser light inside the wavelength conversion member; and cleaving the wavelength conversion member with the modified portion being a starting point, which includes pressing the wavelength conversion member from a first surface side.

### CROSS-REFERENCE TO RELATED APPLICATIONS

This application is based on and claims priority to Japanese Patent Application No. 2023-121810, filed on Jul. 26, 2023, and Japanese Patent Application No. 2024-034603, filed on Mar. 7, 2024, the entire contents of which are incorporated herein by reference.

### BACKGROUND

The present disclosure relates to a method of manufacturing an optical member, and a light emitting device.

There has been a known light emitting device in which a plate-shaped optical member such as a wavelength conversion member is disposed on a light emitting element and a reflective member covers lateral surfaces of the light emitting element and lateral surfaces of the optical member. As an example, Japanese Patent Publication No. 2018-97060 describes a method of obtaining a wavelength conversion member by forming a breaking groove in a first principal surface of a base material and cleaving the base material along the breaking groove, and also describes a light emitting device in which lateral surfaces of the wavelength conversion member are covered by a reflective member such as a resin.

### SUMMARY

It is an object of one embodiment of the present disclosure to provide a method of manufacturing an optical member having good adhesion to a covering member.

A method of manufacturing an optical member according to one embodiment of the present disclosure includes: providing a polycrystalline wavelength conversion member including phosphor particles and having a first surface and a second surface opposite to the first surface; forming a modified portion inside the wavelength conversion member by focusing laser light inside the wavelength conversion member; and pressing the wavelength conversion member from a first surface side to cleave the wavelength conversion member with the modified portion being a starting point.

### BRIEF DESCRIPTION OF THE DRAWINGS

FIG. 1 is a perspective view schematically illustrating an optical member according to a first embodiment;

FIG. 2 is a cross-sectional view of the optical member taken through line II-II of FIG. 1;

FIG. 3 is a schematic diagram (part 1) illustrating a method of manufacturing an optical member according to the first embodiment;

FIG. 4A and FIG. 4B are schematic diagrams (part 2) illustrating the method of manufacturing the optical member according to the first embodiment;

FIG. 5A and FIG. 5B are schematic diagrams (part 3) illustrating the method of manufacturing the optical member according to the first embodiment;

FIG. 6A and FIG. 6B are schematic diagrams illustrating a method of manufacturing an optical member according to a modification of the first embodiment;

FIG. 7 is a perspective view schematically illustrating a light emitting device according to a second embodiment;

FIG. 8 is a cross-sectional view of the light emitting device taken through line VIII-VIII of FIG. 7;

FIG. 9 is a diagram illustrating laser micrographs of the lateral surfaces of wavelength conversion members; and

FIG. 10 is a table illustrating measurement results of Sa and Ra of the lateral surfaces of the wavelength conversion members.

### DETAILED DESCRIPTION

A manufacturing method according to an embodiment of the present disclosure and an optical member obtained by the manufacturing method (which hereinafter may be referred to as an “optical member according to an embodiment”) will be described below with reference to the accompanying drawings. In the following description, terms indicating specific directions and positions (for example, “upper,” “upward,” “lower,” “downward,” and other terms related to these terms) are used as necessary. These terms are used to facilitate understanding of the present invention with reference to the drawings, and the technical scope of the present invention is not limited by the meaning of these terms. The same reference numerals appearing in a plurality of drawings refer to the same or similar portions or members.

Further, the embodiments described below exemplify a method of manufacturing an optical member or the like to embody the technical ideas of the present invention, but the present invention is not limited to the following description. In addition, unless otherwise specified, the dimensions, materials, shapes, relative arrangements, and the like of components described below are described as examples, and are not intended to limit the scope of the present invention thereto. The contents described in one embodiment can be applied to other embodiments and modifications. The sizes, positional relationships, and the like of members illustrated in the drawings may be exaggerated for clearer illustration. Furthermore, to avoid excessive complication of the drawings, a schematic view in which some elements are not illustrated may be used, or an end view illustrating only a cut surface may be used as a cross-sectional view.

### Optical Member 50 According to First Embodiment

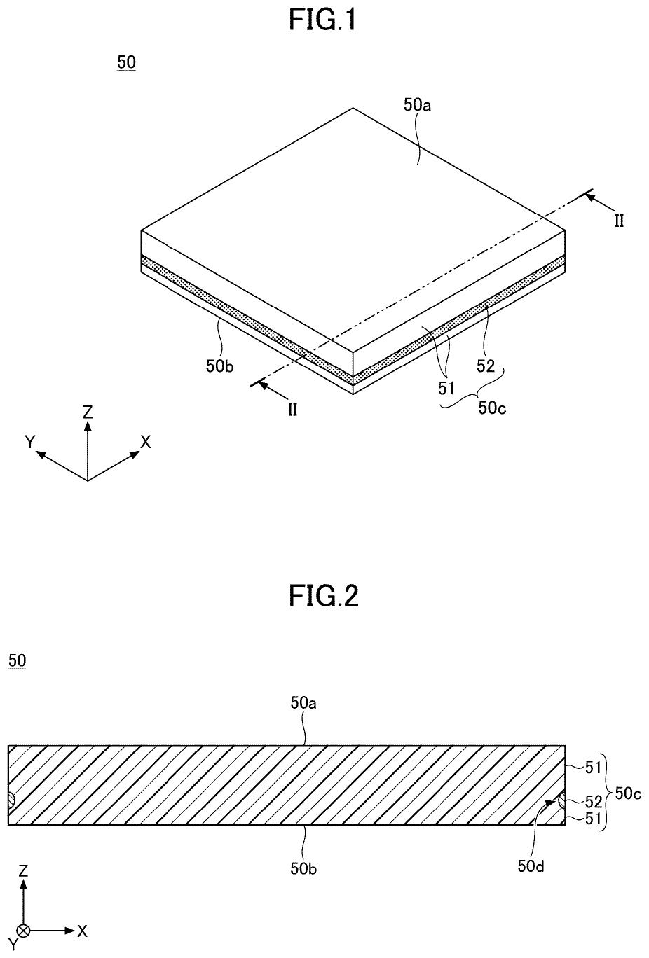

FIG. 1 is a perspective view schematically illustrating an optical member according to a first embodiment. FIG. 2 is a cross-sectional view of the optical member taken through line II-II of FIG. 1. In FIG. 1 and FIG. 2, an X direction and a Y direction orthogonal to each other are defined, and a direction orthogonal to the X direction and the Y direction is defined as a Z direction. In the other drawings, the X direction, the Y direction, and the Z direction may be indicated in the same manner.

As illustrated in FIG. 1 and FIG. 2, the optical member 50 has a plate shape. The optical member 50 has a first surface 50a, a second surface 50b opposite to the first surface 50a, and lateral surfaces 50c that are connected with the first surface 50a and the second surface 50b. The lateral surfaces 50c connects the outer edge of the first surface 50a and the outer edge of the second surface 50b. In the optical member 50, the first surface 50a and the second surface 50b are flat surfaces.

The optical member 50 has, for example, a rectangular parallelepiped shape. In this case, the first surface 50a and the second surface 50b of the optical member 50 both have a rectangular shape, and the optical member 50 has four rectangular lateral surfaces 50c. As used herein, the rectangular shape refers to a rectangle or a square. In the example of FIG. 1 and FIG. 2, the first surface 50a and the second surface 50b are parallel to the XY plane. The lateral surfaces 50c are parallel to the XZ plane or the YZ plane. The Z direction is a height direction (thickness direction) of the optical member 50.

The optical member 50 is a polycrystalline wavelength conversion member containing phosphor particles. The optical member 50 is configured to convert incident light into light having a different wavelength and emit the converted light. The optical member 50 may emit a portion of the incident light. The optical member 50 may convert all the incident light into light having a different wavelength. In this case, the light incident on the optical member 50 is not emitted from the optical member 50.

The optical member 50 is a light transmissive member. In a light emitting device including a light emitting element, the optical member 50 can be used as a member constituting a light emitting surface of the light emitting device. The optical member 50 can adjust the light emission chromaticity of the light emitting device by converting light, emitted from the light emitting element and incident on the second surface 50b, into light having a different wavelength, and emitting the converted light from the first surface 50a.

The optical member 50 includes, at different positions in the height direction (Z direction) of a lateral surface 50c, a first region 51 where the surfaces of phosphor particles are exposed and a second region 52 where the cross sections of phosphor particles are exposed. The cross sections of phosphor particles are cut surfaces obtained by cleaving the phosphor particles. The optical member 50 may include a plurality of first regions 51 at different positions in the height direction (Z direction) of the lateral surface 50c such that the plurality of first regions 51 are spaced apart from each other.

The first region 51 is continuously located over all the lateral surfaces 50c of the optical member 50 along the outer edge of the first surface 50a of the optical member 50. In addition, the optical member 50 may include a first region 51 that is continuously provided over all the lateral surfaces 50c of the optical member 50 along the outer edge of the second surface 50b of the optical member 50. The first region 51 may be located intermittently over all the lateral surfaces 50c of the optical member 50.

In the optical member 50, the second region 52 may be located continuously over all the lateral surfaces 50c of the optical member 50, or may be located intermittently. A plurality of second regions 52 may be provided at different positions in the height direction of a lateral surface 50c such that the plurality of second regions 52 are spaced apart from each other. In this case, a first region is located between adjacent ones of the plurality of second regions. The second region 52 is a surface where a modified portion 50d in a polycrystal is exposed on the lateral surface 50c of the optical member 50. The modified portion 50d can be formed by being irradiated with laser light in a manufacturing process of the optical member 50 as will be described later. The modified portion 50d is a portion where individual materials constituting the polycrystalline optical member 50 including phosphor particles are locally melted by heat energy of the laser light, and where individual crystalline grains are melted and grain boundaries are partially mixed. The modified portion 50d is formed along a region inward of the second region 52.

The surface roughness of the first region 51 is greater than the surface roughness of the second region 52 on the lateral surface of the optical member 50. The surface roughness of the first region 51 is, for example, greater than 1.0 μm and is, for example, 2.0 μm or more and 3.0 μm or less in terms of the arithmetic average roughness Ra, according to the particle size of phosphor particles constituting a polycrystal. In contrast, the surface roughness of the second region 52 is, for example, 0.5 μm or more and 1.0 μm or less in terms of the arithmetic average roughness Ra.

As described, the optical member 50 includes, at different positions in the height direction of the lateral surface 50c, the first region 51 where the surfaces of phosphor particles are exposed and the second region where the cross sections of phosphor particles are exposed. The surface roughness of the first region 51 is greater than the surface roughness of the second region 52. Therefore, in a case where the optical member 50 is used in a light emitting device or the like and the optical member 50 is covered by a covering member 60 such as a resin, with the covering member 60 being in contact with the first region 51 of the optical member 50, the adhesion between the covering member 60 and the optical member 50 can be improved.

From the viewpoint of the adhesion between the optical member 50 and the covering member 60, the area formed by the first region 51 of the lateral surface 50c of the optical member 50 is preferably larger than the area formed by the second region 52. In a light emitting device 1 including the optical member 50 and the covering member 60, with the lateral surface 50c of the optical member 50 having the first region 51 of a larger area, the adhesion between the optical member 50 and the covering member 60 can be improved by an anchor effect of the uneven surface of the first region 51.

Further, in the optical member 50, the second region 52 is preferably provided over all the lateral surfaces 50c so as to be parallel to the upper ends of the lateral surfaces 50c. Accordingly, in a manufacturing method of the light emitting device 1, variations in the speed at which an uncured resin forming the covering member 60 climbs up along the lateral surfaces 50c can be controlled, and variations in the height of covering positions, which depend on the rising speed, can be controlled. That is, the optical member 50 includes the second region 52 on the lateral surfaces 50c such that the second region 52 is parallel to the upper ends of the lateral surfaces 50c, and thus local and excessive climbing-up of an uncured region can be reduced. Accordingly, climbing-up of a resin to the upper surface of the optical member 50 constituting the light emitting surface of the light emitting device 1 can be reduced.

The optical member 50 is a polycrystalline wavelength conversion member including phosphor particles. Examples of the optical member 50 include a sintered body of a phosphor, a sintered body including a phosphor and an inorganic material, and the like.

Examples of a phosphor included in the optical member 50 include yttrium aluminum garnet based phosphors (for example, (Y,Gd)₃(Al,Ga)₅O₁₂:Ce), lutetium aluminum garnet based phosphors (for example, Lu₃(Al,Ga)₅O₁₂:Ce), terbium aluminum garnet based phosphors (for example, Tb₃(Al,Ga)₅O₁₂:Ce), CCA based phosphors (for example, Ca₁₀(PO₄)₆Cl₂:Eu), SAE based phosphors (for example, Sr₄Al₁₄O₂₅:Eu), chlorosilicate based phosphors (for example, Ca₈MgSi₄O₁₆Cl₂:Eu), silicate based phosphors (for example, (Ba,Sr,Ca,Mg)₂SiO₄:Eu), oxynitride based phosphors such as β-SiAlON based phosphors (for example, (Si,Al)₃(O,N)₄:Eu) and α-SiAlON based phosphors (for example, Ca(Si,Al)₁₂(O,N)₁₆:Eu), nitride based phosphors such as LSN based phosphors (for example, (La,Y)₃Si₆N₁₁:Ce), BSESN based phosphors (for example, (Ba,Sr)₂Si₅N₈:Eu), SLA based phosphors (for example, SrLiAl₃N₄:Eu), CASN based phosphors (for example, CaAlSiN₃:Eu), and SCASN based phosphors (for example, (Sr,Ca)AlSiN₃:Eu), fluoride based phosphors such as KSF based phosphors (for example, K₂SiF₆:Mn), KSAF based phosphors (for example, K₂(Si₁₋ₓAlₓ)F₆₋ₓ:Mn, where x satisfies 0<x<1), and MGF based phosphors (for example, 3.5MgO·0.5MgF₂·GeO₂:Mn), quantum dots having a Perovskite structure (for example, (Cs,FA,MA)(Pb,Sn)(F,Cl,Br,I)₃, where FA and MA represent formamidinium and methylammonium, respectively), II-VI quantum dots (for example, CdSe), III-V quantum dots (for example, InP), and quantum dots having a chalcopyrite structure (for example, (Ag,Cu)(In,Ga)(S,Se)₂).

Examples of an inorganic material included in the optical member 50 include aluminum oxide, aluminum nitride, silicon oxide, yttrium oxide, zirconium oxide, or magnesium oxide, gadolinium oxide, and yttrium aluminum perovskite (YAP), and the like.

The average particle size of phosphor particles included in the optical member 50 can be, for example, 1 μm or more and 30 μm or less. The average particle size of an inorganic material included in the optical member 50 can be, for example, 1 μm or more and 20 μm or less. The average particle size of each material included in the optical member 50 can be calculated from an SEM image captured by using a scanning microscope. For example, in an SEM image of a cross section of the optical member 50, the maximum width of a cross section of the crystal phase demarcated by a grain boundary and the minimum width of the cross section passing a center point of the maximum width are measured, and an average of the maximum width and the minimum width is defined as a particle size. In addition, an arithmetic average value of particle sizes in a specific range of an SEM image with the same magnification is defined as an average value of the particle sizes.

### Method of Manufacturing Optical Member According to First Embodiment

A method of manufacturing an optical member according to the first embodiment includes steps of: preparing a polycrystalline wavelength conversion member including phosphor particles and having a first surface and a second surface opposite to the first surface; condensing laser light into the wavelength conversion member to form a modified portion inside the wavelength conversion member; and cleaving the wavelength conversion member with the modified portion being a starting point by pressing the wavelength conversion member from a first surface side.

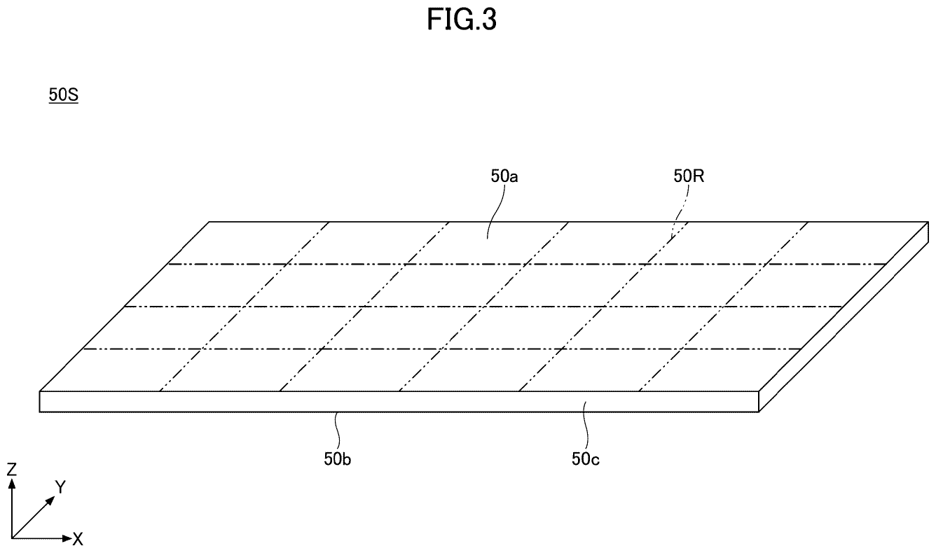

Each of the manufacturing steps of the method of manufacturing the optical member according to the first embodiment will be described below with reference to the drawings. FIG. 3 to FIG. 5B are schematic diagrams

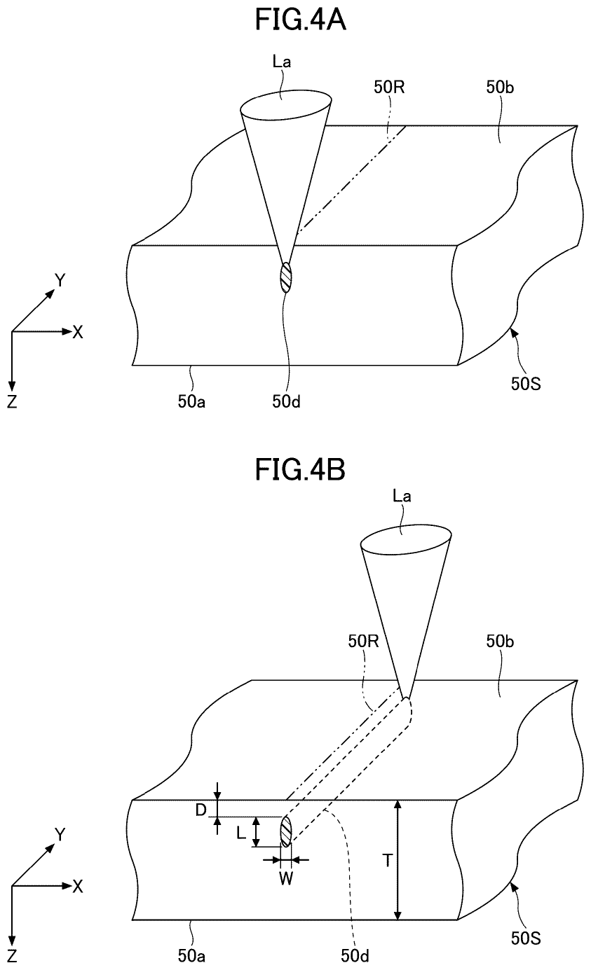

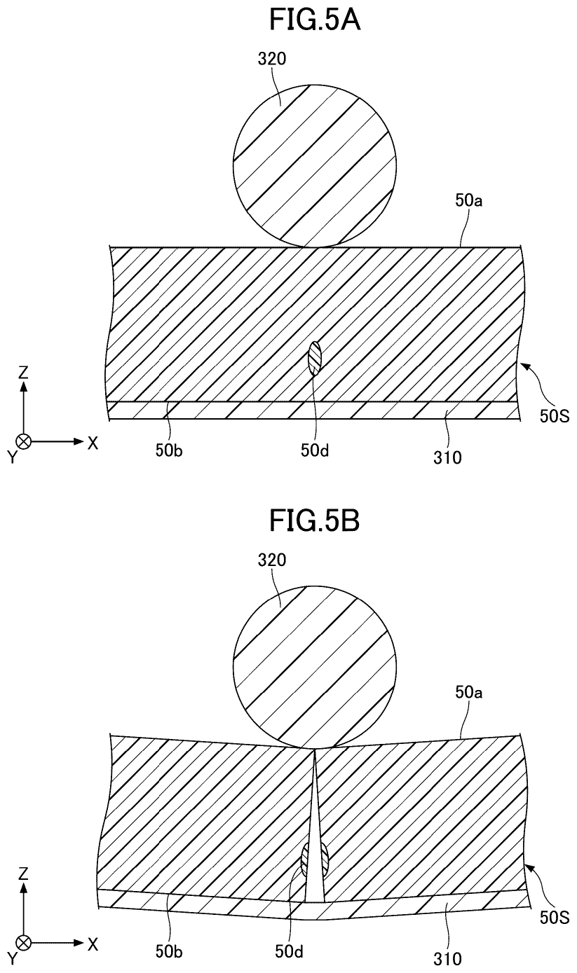

illustrating the method of manufacturing the optical member according to the first embodiment. Specifically, FIG. 3 to FIG. 4B are perspective views illustrating the method of manufacturing the optical member. FIG. 5A and FIG. 5B are cross-sectional views illustrating the method of manufacturing the optical member.

### Step of Preparing Wavelength Conversion Member

As illustrated in FIG. 3, a polycrystalline wavelength conversion member 50S including phosphor particles and having a first surface 50a, a second surface 50b opposite to the first surface 50a, and a lateral surface 50c connected with the first surface 50a and the second surface 50b is prepared. In the example of FIG. 3, the first surface 50a and the second surface 50b are parallel to the XY plane. The lateral surface 50c is parallel to the XZ plane or the YZ plane. The Z direction is the height direction (thickness direction) of the wavelength conversion member 50S. The thickness of the prepared wavelength conversion member is, for example, 50 μm or more and 200 μm or less.

The wavelength conversion member 50S includes a plurality of regions 50R, each of which serves as an optical member 50 after the wavelength conversion member 50S is singulated. In the example of FIG. 3, the boundaries of the regions 50R are defined by two-dot dash straight lines extending in the X direction and two-dot dash straight lines extending in the Y direction. The regions 50R are two-dimensionally arranged in a matrix in a top view of the wavelength conversion member 50S. In the example of FIG. 3, each of the regions 50R has a square shape in the top view of the wavelength conversion member 50S. The two-dot dash lines are virtual lines indicating the boundaries and are not actually visually recognized. Step of Forming Modified Portion

Next, as illustrated in FIG. 4A and FIG. 4B, a modified portion 50d is formed inside the wavelength conversion member 50S by focusing laser light La inside the wavelength conversion member 50S.

The laser light La can be emitted from, for example, a picosecond laser device or a femtosecond laser device. The laser light La has an oscillation wavelength of, for example, 700 nm or more and 1,500 nm or less. The wavelength conversion member 50S preferably has a light transmittance of 60% or more with respect to the laser light La.

Specifically, as illustrated in FIG. 4A, the laser light La is emitted in a direction substantially perpendicular to the second surface 50b of the wavelength conversion member 50S. The second surface 50b is irradiated with the laser light La at positions on a two-dot dash line indicating the boundary of regions 50R. The laser light La is focused at positions inside the wavelength conversion member 50S and closer to the second surface 50b than the center of the wavelength conversion member 50S in the thickness direction (Z-direction).

As illustrated in FIG. 4A, the laser light La is irradiated, for example, onto the two-dot dash line extending in the Y direction and indicating the boundary of the regions 50R. Accordingly, as illustrated in FIG. 4B, a modified portion 50d is formed inside the wavelength conversion member 50S along the Y direction in a top view. In the step of cleaving the wavelength conversion member as will be described later, a portion where the modified portion 50d is not formed is divided along grain boundaries with the modified portion 50d being a starting point. Therefore, the modified portion 50d is preferably formed in a linear shape in a top view.

As illustrated in FIG. 3, if there are a plurality of (in the example of FIG. 3, five) two-dot dash lines indicating the boundaries of regions 50R along the Y direction, the laser light La is sequentially irradiated along each of the two-dot dash lines such that a modified portion 50d is formed inside the wavelength conversion member at each condensing position.

Next, the laser light La is irradiated along a two-dot dash line extending in the X direction and indicating the boundary of regions 50R. As a result, a modified portion 50d is formed in a linear shape inside the wavelength conversion member 50S along the X direction in a top view. As illustrated in FIG. 3, if there are a plurality of (in the example of FIG. 3, three) two-dot dash lines indicating the boundaries of regions 50R, the laser light La is emitted along each of the plurality of two-dot dash lines such that a modified portion 50d is formed inside the wavelength conversion member 50S at each condensing position.

In the above-described manner, modified portions 50d are formed inside the wavelength conversion member 50S in a grid pattern such that the modified portions 50d overlap the boundaries of the regions 50R in the top view of the wavelength conversion member 50S. Each of the modified portions 50d may be formed inside the wavelength conversion member 50S at a position spaced apart from the first surface 50a and the second surface 50b of the wavelength conversion member 50S, or may be formed inside the wavelength conversion member 50S so as to be connected with the first surface 50a and the second surface 50b. Each of the modified portions 50d is preferably formed at a position spaced apart from the first surface 50a and the second surface 50b. By irradiating with the laser light La so that the laser light La is focused inside the wavelength conversion member 50S, the modified portions 50d can be located spaced apart from the first surface 50a and the second surface 50b of the wavelength conversion member 50S. With the arrangement of the modified portions 50d described above, contamination due to burnout, adhesion of dust such as fumes to the first surface 50a and the second surface 50b, or the like, caused by irradiation of the laser light La when the modified portions 50d are formed, can be reduced.

As illustrated in FIG. 4B, in the step of forming a modified portion, a modified portion 50d is preferably formed in a region at a depth D of greater than 0 and 10 μm or less from the second surface 50b of the wavelength conversion member 50s. The depth D is a distance from the second surface 50b to a position within the modified portion 50d, the position closest to the second surface 50b in the Z direction.

In consideration of ease of cleaving the wavelength conversion member 50S and adhesion to the covering member 60 in the light emitting device 1, the length L of the modified portion 50d in the depth direction (Z direction) of the wavelength conversion member 50S is preferably 2% or more and 30% or less of the thickness T of the wavelength conversion member 50S. Further, the width W of the modified portion 50d in a direction parallel to the second surface 50b of the wavelength conversion member 50S is preferably 1 μm or more and 10 μm or less.

By setting the length L of the modified portion 50d to 2% or more of the thickness T of the wavelength conversion member 50S and setting the width W of the modified portion 50d to 1 μm or more, the wavelength conversion member 50S can be easily cleaved along the modified portion 50d. By setting the length L of the modified portion 50d to 30% or less of the thickness T of the wavelength conversion member 50S and setting the width W of the modified portion 50d to 10 μm or less, the area of a first region on a lateral surface 50c of an optical member 50 to be formed can be increased, and the adhesion between the optical member 50 and the covering member 60 can be improved.

For ease of cleaving the wavelength conversion member 50S, the length L of the modified portion 50d in the depth direction (Z direction) of the wavelength conversion member 50S may be 30% or more of the thickness T of the wavelength conversion member 50S. However, the modified portion 50d is considered to be a region where the wavelength conversion efficiency is reduced by the irradiation of the laser light. Thus, from the viewpoint of improving the light extraction efficiency of the light emitting device 1, the length L of the modified portion 50d with respect to the thickness T of the wavelength conversion member 50S is preferably set to be in the above-described range.

The modified portion 50d is formed when the energy of the laser light La at the condensing position exceeds a processing threshold of the material of the wavelength conversion member 50S. The length L increases as the energy of the laser light La at the condensing position increases. The width W is smaller than the spot diameter of the laser light La at the condensing position.

### Step of Cleaving Wavelength Conversion Member

Next, the wavelength conversion member 50S is cleaved with the modified portion 50d being a starting point by pressing the wavelength conversion member 50S from the first surface 50a side. In this step, for example, the wavelength conversion member 50S can be cleaved by pressing the wavelength conversion member 50S along the linear-shaped modified portion 50d.

Specifically, a crack is generated in the modified portion 50d formed by the irradiation of the laser light La, and the wavelength conversion member 50S is pressed to be cleaved with the crack, which propagates from the modified portion 50d, being a starting point. In a region where the modified portion 50d is not formed, the crack propagates along the grain boundaries of the polycrystalline wavelength conversion member 50S in the pressing direction.

As an example, a cleaving method using a support member 310 and a pressing member 320 will be described. First, as illustrated in FIG. 5A, the support member 310 is disposed on the second surface 50b of the wavelength conversion member 50S, and the wavelength conversion member 50S is pressed by the pressing member 320 from the first surface 50a side.

The support member 310 is preferably elastically deformable by being pressed by the pressing member 320. The support member 310 can be formed of, for example, rubber, resin, metal, or the like. The support member 310 elastically deforms by being pressed by the pressing member 320, which allows the wavelength conversion member 50S to be locally pressed, and thus the wavelength conversion member 50S can be easily cleaved along the modified portion 50d.

The pressing member 320 may be caused to press the entire first surface 50a at once or may be caused to press a portion of the first surface 50a. The pressing member 320 is preferably configured to move on the first surface 50a while pressing a portion of the first surface 50a. Examples of the pressing member 320 include a member such as a roller that can move on the first surface 50a while being rotated. The pressing member 320 may be a member that does not rotate as long as the pressing member 320 can smoothly move on the first surface 50a. In the example of FIG. 5A and FIG. 5B, the pressing member 320 has an elongated cylindrical shape, and the pressing member 320 is disposed with its longitudinal direction being in the Y direction.

For example, the pressing member 320 presses the wavelength conversion member 50S while moving on the first surface 50a in a direction (the X direction in the example of FIG. 5A and FIG. 5B) perpendicular to a direction (the Y direction in the example of FIG. 5A and FIG. 5B) along which the modified portion 50d is formed. Accordingly, the wavelength conversion member 50S is pressed along the modified portion 50d formed in a linear shape in a plan view, and as illustrated in FIG. 5B, the wavelength conversion member 50S is cleaved with the modified portion 50d being a starting point. Next, the pressing member 320 is rotated by 90 degrees in the XY plane such that the longitudinal direction of the pressing member 320 corresponds to the X direction. Then, the pressing member 320 presses the wavelength conversion member 50S while moving on the first surface 50a in the Y direction of FIG. 5A and FIG. 5B. In this manner, all modified portions 50d arranged in a grid pattern can be cleaved, so that a plurality of singulated optical members 50 can be obtained.

A modified portion 50d formed inside the wavelength conversion member 50S is not easily observed from the first surface 50a side, and thus it is difficult to align the position at which the pressing member 320 presses the wavelength conversion member 50S with the position of the modified portion 50d. However, by pressing the wavelength conversion member 50S in one direction while causing the pressing member 320 to move on the first surface 50a, the wavelength conversion member 50S can be easily cleaved even when the position of the modified portion 50d is not accurately recognized. In addition, by providing the wavelength conversion member 50S with a mark indicating a direction along which the modified portion 50d is formed, a direction in which the pressing member 320 is moved can be easily determined with respect to the direction along which the modified portion 50d is formed.

Each of the optical members 50 obtained after the wavelength conversion member 50S is cleaved includes a first region 51, where the surfaces of phosphor particles are exposed, and a second region 52, where the cross sections of phosphor particles are exposed, at different positions in the height direction of a lateral surface 50c as illustrated in FIG. 1 and FIG. 2. The second region 52 is the cleaved surface of the modified portion 50d.

As described, by forming the modified portion 50d inside the wavelength conversion member 50S, even if the length L and width W of the modified portion 50d are small, the wavelength conversion member 50S can be easily cleaved along the modified portion 50d with the modified portion 50d being a starting point of cracking.

Further, for example, if the wavelength conversion member 50S is cut by dicing using a blade, a cutting allowance corresponding to the width of the blade would be required. However, in a method of cutting the wavelength conversion member 50S along the modified portion 50d as in the manufacturing method according to the present embodiment, substantially no cutting allowance is required, and thus the number of optical members 50 obtained from the wavelength conversion member 50S can be increased.

### Modification

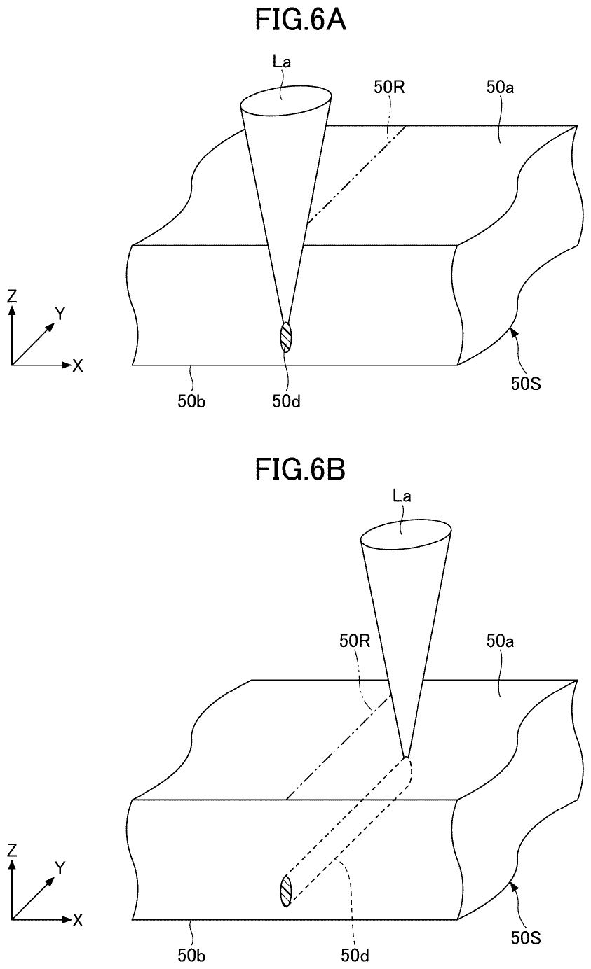

FIG. 6A and FIG. 6B are schematic diagrams illustrating a method of manufacturing an optical member according to a modification of the first embodiment. Specifically, FIG. 6A and FIG. 6B are perspective views illustrating the method of manufacturing the optical member.

In the first embodiment, an example in which the laser light La is irradiated from the second surface 50b side opposite to the side (first surface 50a side) that is pressed at the time of cleaving has been described. In the modification of the first embodiment, as illustrated in FIG. 6A and FIG. 6B, the laser light La is irradiated from the side (first surface 50a side) that is pressed at the time of cleaving.

Specifically, as illustrated in FIG. 6A, the laser light La is irradiated in a direction substantially perpendicular to a first surface 50a of a wavelength conversion member 50S. The laser light La is focused at positions deeper than that of the first embodiment. That is, the laser light La is focused at positions inside the wavelength conversion member 50S, the positions closer to a second surface 50b than the center of the wavelength conversion member 50S in the height direction (Z direction).

By irradiating with the laser light La along a two-dot dash line extending in the Y direction and indicating the boundary of regions 50R, a modified portion 50d is continuously formed in a linear shape along the Y direction in a top view inside the wavelength conversion member 50S as illustrated in FIG. 6B.

Subsequently, the laser light La is irradiated along a virtual line extending in the X direction and indicating the boundary of regions 50R. Accordingly, a modified portion 50d is continuously formed in a linear shape along the X direction in a top plan view inside the wavelength conversion member 50S.

In this manner, even when the laser light La is irradiated from the first surface 50a side, focusing the laser light La at deeper positions allows the modified portion 50d to be formed closer to the second surface 50b as in the first embodiment. Thereafter, as described in the first embodiment with reference to FIG. 5A and FIG. 5B, the wavelength conversion member 50S is pressed from the first surface 50a side to be cleaved, so that a plurality of singulated optical members 50 can be obtained.

### Second Embodiment

In a second embodiment, an example of a light emitting device including the optical member according to the first embodiment will be described.

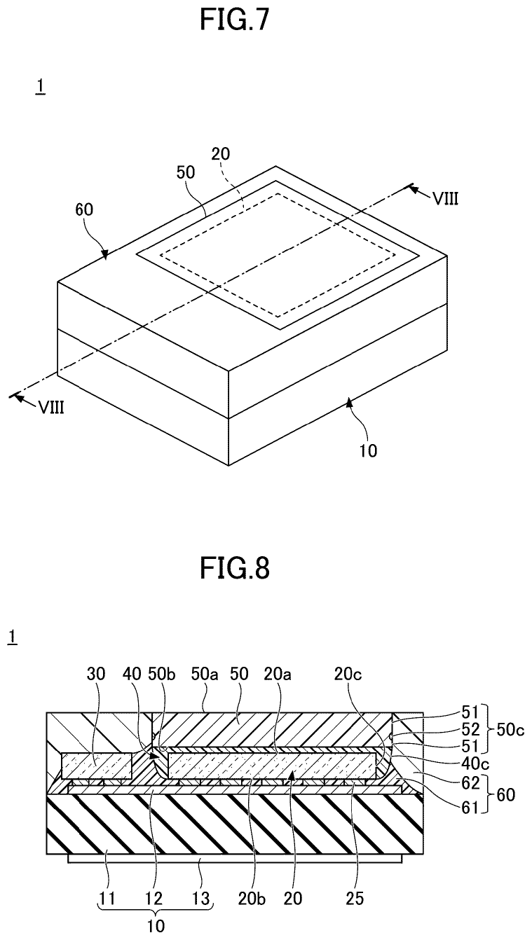

FIG. 7 is a perspective view schematically illustrating the light emitting device according to the second embodiment. FIG. 8 is a cross-sectional view of the light emitting device taken through line VIII-VIII of FIG. 7. FIG. 8 illustrates a cross section of the light emitting device 1 taken along a plane perpendicular to the upper surface of a light emitting element 20.

As illustrated in FIG. 7 and FIG. 8, the light emitting device 1 includes a wiring substrate 10, the light emitting element 20, a protective element 30, a light guide member 40, the optical member 50, and the covering member 60. The light emitting device 1 may have a configuration in which the wiring substrate 10, the protective element 30, the light guide member 40, and the covering member 60 are not included.

In the light emitting device 1, the light emitting element 20 is disposed on the wiring substrate 10. The light emitting element 20 has an upper surface 20a, a plurality of lateral surfaces 20c connected to the upper surface 20a, and a lower surface 20b opposite to the upper surface 20a. The plurality of lateral surfaces 20c are connected to the upper surface 20a and the lower surface 20b. In other words, each of the lateral surfaces 20c has outer edges connected to the outer edge of the upper surface 20a and to the outer edge of the lower surface 20b. Light is emitted from the upper surface 20a, the lower surface 20b, and the lateral surface(s) 20c of the light emitting element 20. Further, in the light emitting device 1, the protective element 30 may be disposed on the wiring substrate 10.

The light emitting element 20 has the upper surface 20a having a substantially rectangular shape. For example, the exterior shape of the light emitting element 20 is a substantially rectangular parallelepiped shape or a substantially truncated pyramid shape. In this case, the upper surface 20a and the lower surface 20b of the light emitting element 20 has a substantially rectangular shape, and the light emitting element 20 has four lateral surfaces 20c each having a substantially rectangular shape or a substantially trapezoidal shape. The upper surface 20a of the light emitting element 20 may have a polygonal shape such as a triangular shape or a hexagonal shape. Further, the external shape of the light emitting element 20 may be a columnar shape or a frustum shape having a polygonal-shaped upper surface.

The light guide member 40 continuously covers the upper surface 20a and the plurality of lateral surfaces 20c connected to the upper surface 20a of the light emitting element 20. Specifically, the light guide member 40 covers the entire upper surface 20a and at least a portion on the upper end side (that is, the outer edge side connected to the upper surface 20a) of each of the lateral surfaces 20c of the light emitting element 20. The light guide member 40 has lateral surfaces 40c that is in contact with the lateral surfaces 20c of the light emitting element 20 and is in contact with the lower surface of the optical member 50. The light guide member 40 preferably covers a larger region of each of the lateral surfaces 20c of the light emitting element 20, and more preferably covers approximately a entirety of each of the lateral surfaces 20. That is, the lateral surfaces 40c of the light guide member 40 are preferably in contact with the lateral surfaces 20c of the light emitting element 20 at positions close to the lower ends (on the side connected to the lower surface 20b) of the lateral surfaces 20c, and are more preferably in contact with the lower ends of the lateral surfaces 20c. Specifically, a region in the range of 75% to 100% from the upper end of each of the lateral surfaces 20c in the height direction of the light emitting element 20 is preferably covered by the light guide member 40, and a region in the range of 90% to 100% from the upper end of each of the lateral surfaces 20c in the height direction of the light emitting element 20 is more preferably covered by the light guide member 40.

The optical member 50 is disposed over the light emitting element 20 with the light guide member 40 disposed therebetween. As described in the first embodiment, the optical member 50 is a polycrystalline wavelength conversion member including phosphor particles. The optical member 50 includes, at different positions in the height direction of the lateral surface(s) 50c, the first region 51 where the surfaces of phosphor particles are exposed and the second region 52 where the cross sections of phosphor particles are exposed. Details of the first region 51 and the second region 52 are the same as those described in the first embodiment.

The first surface 50a of the optical member 50 constitutes a part of the upper surface of the light emitting device 1 and serves as a light-extracting surface of the light emitting device 1. The light guide member 40 is disposed on the upper surface 20a of the light emitting element 20, and the optical member 50 is disposed over the light emitting element 20 with the light guide member 40 disposed therebetween such that the second surface 50b of the optical member 50 faces the upper surface 20a of the light emitting element 20. The optical member 50 is disposed such that the second surface 50b of the optical member 50 is substantially parallel to the upper surface 20a of the light emitting element 20. The shape of the second surface 50b of the optical member 50 is preferably similar to the shape of the upper surface 20a of the light emitting element 20. For example, when the upper surface 20a of the light emitting element 20 has a rectangular shape, the second surface 50b of the optical member 50 preferably has a rectangular shape.

The area of the second surface 50b of the optical member 50 is preferably larger than the area of the upper surface 20a of the light emitting element 20. Further, the optical member 50 is preferably disposed to surround the outer periphery of the light emitting element 20 in a top view. Further, in the light emitting device 1, the light guide member 40, which is disposed between the second surface 50b of the optical member 50 and the upper surface 20a of the light emitting element 20, preferably covers a portion of the second surface 50b of the optical member 50 that does not overlap with the upper surface 20a of the light emitting element 20 in a top view. Further, in the light emitting device 1, the light guide member 40 preferably reaches the outer edge of the second surface 50b of the optical member 50, and the entire second surface 50b is preferably covered by the light guide member 40.

Accordingly, a larger portion of light emitted from the light emitting element 20 can be incident on the second surface 50b of the optical member 50 through the light guide member 40.

The covering member 60 is provided on the wiring substrate 10 and covers the lateral surfaces 50c of the optical member 50 and the lateral surfaces 20c of the light emitting element 20 such that the first surface 50a of the optical member 50 is exposed from the covering member 60. The covering member 60 may directly cover the lateral surfaces 20c of the light emitting element 20, or may cover the lateral surfaces 20c of the light emitting element 20 via another member such as the light guide member 40. Further, when the light emitting device 1 includes the protective element 30, the covering member 60 preferably covers the upper surface, the lower surface, and the lateral surfaces of the protective element 30. Further, the covering member 60 may cover a portion of the lateral surfaces 20c of the light emitting element 20 exposed from the light guide member 40, and may cover the lower surface 20b of the light emitting element 20.

With the covering member 60 covering the lateral surfaces 40c of the light guide member 40, light emitted from the lateral surfaces 20c of the light emitting element 20 and transmitted through the light guide member 40 is reflected by the covering member 60. Further, by causing the covering member 60 to cover the lower surface 20b of the light emitting element 20, light traveling below the light emitting element 20 is reflected by the covering member 60. Accordingly, the light extraction efficiency of the light emitting device 1 can be improved.

The covering member 60 may be constituted by one member or may be constituted by a plurality of members. In the example illustrated in FIG. 7 and FIG. 8, the covering member 60 includes a first covering member 61 and a second covering member 62. For example, the first covering member 61 is disposed on the wiring substrate 10, and covers at least a portion of the lower surface 20b of the light emitting element 20 and at least a portion of at least one of the lateral surfaces 40c of the light guide member 40. When the light emitting device 1 includes the protective element 30, the first covering member 61 covers, for example, at least a portion of the lower surface and at least a portion of at least one of the lateral surfaces of the protective element 30.

For example, the second covering member 62 is disposed on the first covering member 61, and covers the lateral surfaces of the optical member 50. When the light emitting device 1 includes the protective element 30, the second covering member 62 covers the upper surface of the protective element 30, for example. The second covering member 62 may cover portions of the lateral surfaces of the optical member 50 and portions of the lateral surfaces of the protective element 30.

The lateral surfaces of the second covering member 62 and the lateral surfaces of a base 11 of the wiring substrate 10 constitute the lateral surfaces of the light emitting device 1. Some lateral surfaces of the second covering member 62 can be, for example, coplanar with respective ones of the lateral surfaces of the base 11. Further, the upper surface of the second covering member 62 can be, for example, coplanar with the first surface 50a of the optical member 50.

As described above, in the light emitting device 1, the optical member 50 includes, at different positions in the height direction of the lateral surface(s) 50c, the first region 51 where the surfaces of phosphor particles are exposed, and the second region 52 where the cross sections of phosphor particles are exposed. The surface roughness of the first region 51 is greater than the surface roughness of the second region 52. Therefore, with the covering member 60 being in contact with the first region 51 of the optical member 50, the adhesion between the covering member 60 and the optical member 50 can be improved.

Components of the light emitting device 1 according to the embodiment will be described in detail below.

### Wiring Substrate 10

The wiring substrate 10 is a member on which the light emitting element 20 is disposed. The wiring substrate 10 includes wiring for supplying power to the light emitting element from the outside, and includes the base 11 that supports the wiring. In one example, the wiring substrate 10 includes upper wiring 12 and lower wiring 13. The upper wiring 12 is located at an upper surface of the wiring substrate 10 on which the light emitting element 20 is disposed, and the lower wiring 13 is located at a lower surface of the wiring substrate 10 opposite to the upper surface thereof. The base 11 has, for example, a substantially rectangular parallelepiped shape. The base 11 is preferably formed of an insulating material through which light emitted from the light emitting element 20, external light, or the like is not easily transmitted. Examples of the material of the base 11 include ceramics such as aluminum oxide, aluminum nitride, silicon nitride, and mullite; resins such as epoxy resins, silicone resins, modified epoxy resins, urethane resins, phenol resins, polyimide resins, bismaleimide-triazine resins (BT resins), and polyphthalamide; semiconductors such as silicon; single metal materials such as copper and aluminum; and composite materials of these. Among them, a ceramic having good heat dissipation properties can be suitably used as the material of the base 11.

The upper wiring 12 includes wiring that is electrically connected to the light emitting element 20, and wiring that is electrically connected to the protective element 30. The lower wiring 13 includes an external connection terminal that is electrically connected to an external power source. Examples of the material of each of the upper wiring 12 and the lower wiring 13 include metals such as iron, copper, nickel, aluminum, gold, silver, platinum, titanium, tungsten, and palladium, and an alloy including at least one of these metals. Further, the wiring substrate 10 may include intermediate wiring for connecting the upper wiring 12 and the lower wiring 13. The intermediate wiring may be provided inside the base 11 or on a lateral surface of the base 11.

The wiring substrate 10 does not necessarily include the lower wiring 13. In this case, the external connection terminal that is electrically connected to the external power source may be provided on the upper surface or a lateral surface of the wiring substrate 10.

The light emitting device 1 may have a configuration in which the wiring substrate 10 has a recess in the upper surface thereof, and the light emitting element 20 is disposed on the bottom of the recess of the wiring substrate 10. The light emitting device 1 may have a configuration in which the wiring substrate 10 is not included. For example, the light emitting device 1 may have a configuration in which a metal member, exposed from the covering member 60 covering the lower surface 20b of the light emitting element 20, is included as an electrode of the light emitting device 1.

### Light Emitting Element 20

A semiconductor light emitting element such as a light emitting diode (LED) chip or a semiconductor laser diode (LD) chip can be suitably used as the light emitting element 20. The light emitting element 20 can have any appropriate shape, size, and the like. The light emitting element 20 includes a plurality of electrodes 25 on the lower surface 20b, for example. The light emitting element 20 is disposed on the wiring substrate 10. The light emitting element 20 is flip-chip mounted on the wiring substrate 10 such that the lower surface 20b, on which the electrodes 25 are provided, faces the wiring substrate 10, for example. The plurality of electrodes 25 of the light emitting element 20 are electrically connected to the upper wiring 12. The plurality of electrodes 25 of the light emitting element 20 can be connected to the upper wiring 12 by using a known member such as eutectic solder, conductive paste, or bumps.

The light emitting element 20 includes, for example, a semiconductor structure and a support substrate that supports the semiconductor structure. The semiconductor structure includes an n-side semiconductor layer, a p-side semiconductor layer, and an active layer located between the n-side semiconductor layer and the p-side semiconductor layer. The active layer may have a single quantum well (SQW) structure or a multiple quantum well (MQW) structure including a plurality of well layers. The semiconductor structure includes a plurality of semiconductor layers formed of nitride semiconductors. Examples of the nitride semiconductors include semiconductors of any compositions represented by the chemical formula InₓAl_{y}Ga_{1-x-y}N (0≤x, 0≤y, x+y≤1) where the composition ratio x and y vary within these ranges. The peak emission wavelength of the active layer can be appropriately selected in accordance with the purpose. The active layer is configured to emit, for example, visible light or ultraviolet light.

In the light emitting element 20, a single semiconductor structure may be disposed on a single support substrate, or a plurality of semiconductor stacks may be disposed on a single support substrate. A single semiconductor structure may include a single light emitting layer, or may include a plurality of light emitting layers. A semiconductor structure having a plurality of light emitting layers may be a structure in which a plurality of active layers are located between a single n-side semiconductor layer and a single p-side semiconductor layer, or may be a structure in which an n-type semiconductor layer, an active layer, and a p-type semiconductor layer are repeatedly layered multiple times.

In the light emitting element 20, the plurality of electrodes 25 are disposed on a semiconductor structure. The electrodes 25 include an n-electrode connected to an n-side semiconductor layer and a p-electrode connected to a p-side semiconductor layer. The p-electrode and the n-electrode may be disposed on different surfaces or the same surface of a semiconductor stack. In this example, the plurality of electrodes 25 including the p-electrode and the n-electrode are disposed on the same surface of the semiconductor structure. A surface of the semiconductor structure on which the plurality of electrodes 25 are disposed constitutes the lower surface 20b of the light emitting element 20, and a surface of the support substrate opposite to a surface thereof on which the semiconductor structure are disposed constitutes the upper surface 20a of the light emitting element 20. As the support substrate, an insulating substrate, such as sapphire or spinel (MgAl₂O₄), or a nitride-based semiconductor substrate such as gallium nitride can be used. The support substrate can be preferably formed of a light-transmissive material in order to extract light emitted from the active layer through the support substrate. The light emitting element 20 does not necessarily include the support substrate. In this case, the surface of the semiconductor structure opposite to the surface thereof on which the electrodes are disposed constitutes the upper surface 20a of the light emitting element 20.

### Protective Element 30

The light emitting device 1 can include the protective element 30. The protective element 30 is a member for improving the electrostatic resistance. The protective element 30 is, for example, a Zener diode. The protective element 30 is disposed on the wiring substrate 10.

### Light Guide Member 40

The light guide member 40 is a member that causes light emitted from the light emitting element 20 to travel to the optical member 50. The light guide member 40 covers the lateral surfaces of the light emitting element 20, thereby allowing light emitted from the lateral surfaces of the light emitting element 20 to easily travel to the optical member 50. Accordingly, the light extraction efficiency of the light emitting device 1 can be improved. Further, the light guide member 40 can be used as an adhesive member that bonds the light emitting element 20 and the optical member 50.

The light guide member 40 is disposed to cover the upper surface 20a and each of the lateral surfaces 20c of the light emitting element 20. The light guide member 40 covering the lateral surfaces 20c of the light emitting element 20 can be formed by causing an uncured adhesive resin, which is to bond the optical member 50 and the light emitting element 20 together, to wet and spread over the lateral surfaces 20c of the light emitting element 20 and subsequently curing the adhesive resin. Examples of the adhesive resin, which serves as the light guide member 40 after being cured, include a light-transmissive resin. Examples of the light-transmissive resin include thermosetting resins such as epoxy resins, modified epoxy resins, silicone resins, and modified silicone resins. Among them, a silicone resin having high heat resistance can be suitably used. The light guide member 40 may include a light diffusion member and a phosphor, which will be described later. Alternatively, the light emitting element 20 and the optical member 50 may be directly bonded to each other without using an adhesive resin such as the light guide member 40. In this case, the light emitting device 1 does not necessarily include the light guide member 40.

### Covering Member 60

The covering member 60 preferably has a light shielding property. Specifically, the covering member 60 preferably has light reflectivity and/or light absorbability. The covering member 60 preferably includes a material that can appropriately reflect light emitted from the light emitting element 20. For example, the covering member 60 preferably has a reflectance of 60% or more, and more preferably has a reflectance of 70% or more, 80% or more, or 90% or more with respect to light emitted from the light emitting element 20.

For the covering member 60, an insulating material is preferably used. The covering member 60 is a member formed of a light-transmissive resin containing particles of a light reflective substance. Examples of the resin used for the covering member 60 include a resin including one or more of a silicone resin, a modified silicone resin, an epoxy resin, a modified epoxy resin, a urea resin, an acrylic resin, a phenol resin, a bismaleimide-triazine resin, and a polyphthalamide resin, and a hybrid resin of two or more of these resins. Among them, a silicone resin having good light resistance, heat resistance, electrical insulation, and flexibility is preferably used. Examples of the light reflective substance include titanium oxide, silicon oxide, aluminum oxide, zirconium oxide, magnesium oxide, potassium titanate, barium titanate, zinc oxide, silicon nitride, aluminum nitride, boron nitride, calcium carbonate, calcium hydroxide, calcium silicate, and a combination thereof. Among them, titanium oxide having a relatively high refractive index is preferably used in consideration of light reflection.

As described above, the covering member 60 may include the first covering member 61 and the second covering member 62. In this case, each of the first covering member 61 and the second covering member 62 can be formed of a material selected from the above materials exemplified as the material of the covering member 60. When the covering member 60 includes the first covering member 61 and the second covering member 62, for example, a material with high mechanical strength can be used for the second covering member 62 constituting the outer surface of the light emitting device 1, and a material with low elasticity and low linear expansion can be used for the first covering member 61 covering the lower surface 20b of the light emitting element 20, thus allowing for reducing a stress caused by expansion of a resin.

### Operation of Light Emitting Device 1

In the light emitting device 1, upon supplying an electric current from the external power source to the light emitting element 20, the light emitting element 20 emits light. Of the light emitted from the light emitting element 20, light traveling upward (that is, toward the lower surface of the optical member) is extracted to the outside of the light emitting device 1 through the light guide member 40 and the optical member 50. Further, of the light emitted from the light emitting element 20, light traveling downward is reflected by the covering member 60 and the wiring substrate 10, and is extracted to the outside of the light emitting device 1 through the light guide member 40 and the optical member 50. Further, of the light emitted from the light emitting element 20, light traveling in the lateral direction is reflected by the interface between a lateral surface 40c of the light guide member 40 and the covering member 60, and is extracted to the outside of the light emitting device 1 through the light guide member 40 and the optical member 50.

As described above, in the light emitting device 1, the optical member 50 includes, at different positions on the lateral surface(s) 50c in the height direction of the lateral surface(s) 50c, the first region 51, where the surfaces of phosphor particles are exposed, and the second region 52, where the cross sections of phosphor particles are exposed. The surface roughness of the first region 51 is greater than the surface roughness of the second region 52. Therefore, with the covering member 60 to contact the first region 51 of the optical member 50, the adhesion between the covering member 60 and the optical member 50 can be improved. In particular, the first region 51 is continuous with the upper surface of the optical member 50, which serves as the light emission surface of the light emitting device 1. Therefore, separation at the interface between the optical member 50 and the covering member 60, that is, separation at the light emission surface of the light emitting device 1 can be inhibited, and thus the reliability of the light emitting device 1 can be improved.

### EXAMPLES

Examples will be described in detail below; however, the present invention is not limited to these Examples.

In Example 1, a polycrystalline wavelength conversion member A including phosphor particles was provided. The wavelength conversion member A was a sintered body containing yttrium aluminum garnet (YAG) that has a particle size of 2 μm to 4 μm as a phosphor and yttrium aluminum perovskite (YAP) that has a particle size of 1.5 μm to 2.5 μm as an inorganic diffusion material and having been processed into a wafer shape having a thickness of approximately 180 μm. Subsequently, laser light is focused inside the wavelength conversion member A to form modified portions inside the wavelength conversion member A. Then, the wavelength conversion member A was pressed and cleaved with the modified portions being starting points.

In Example 2, a polycrystalline wavelength conversion member B including phosphor particles was prepared. The wavelength conversion member B was a sintered body containing YAG that has a particle size of 8 μm to 15 μm as a phosphor and aluminum oxide that has a particle size of 5 μm to 10 μm as an inorganic diffusion material and having been processed into a wafer shape having a thickness of approximately 160 μm. Subsequently, laser light is focused inside the wavelength conversion member B to form modified portions inside the wavelength conversion member B. Then, the wavelength conversion member B was pressed and cleaved with the modified portions being starting points.

Next, the lateral surfaces of five samples of each of the cleaved wavelength conversion members A and B were observed with a microscope, and the arithmetic average height Sa and the arithmetic average roughness Ra of the lateral surfaces of each of the samples were measured. The observation of the lateral surfaces and the measurement of Sa and Ra were performed by using a laser scanning microscope VK-X200 (manufactured by Keyence Corporation).

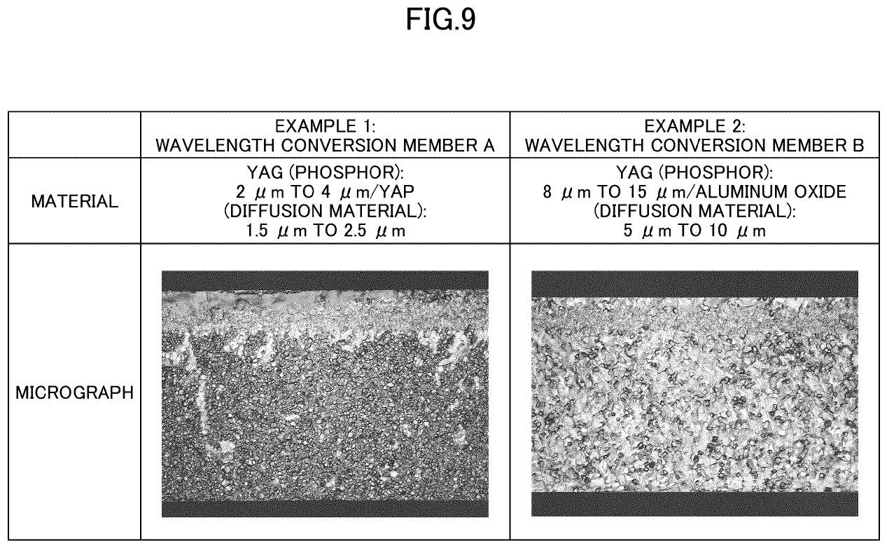

By observing the lateral surface of each of the samples of the wavelength conversion members A and B with the laser microscope, a first region, where the surfaces of phosphor particles were exposed, and a second region, where the cross sections of phosphor particles were exposed, were confirmed at different positions in the height direction on the lateral surface of each of the samples. Examples of observation results are illustrated in FIG. 9. FIG. 9 is a laser micrograph of a portion of the lateral surface of one sample of the wavelength conversion member A and a laser micrograph of a portion of a lateral surface of one sample of the wavelength conversion member B. As illustrated in FIG. 9, a first region with a large surface roughness can be confirmed on the lower side, and a second region having a small surface roughness can be confirmed on the upper side of each of the micrographs of the wavelength conversion members A and B.

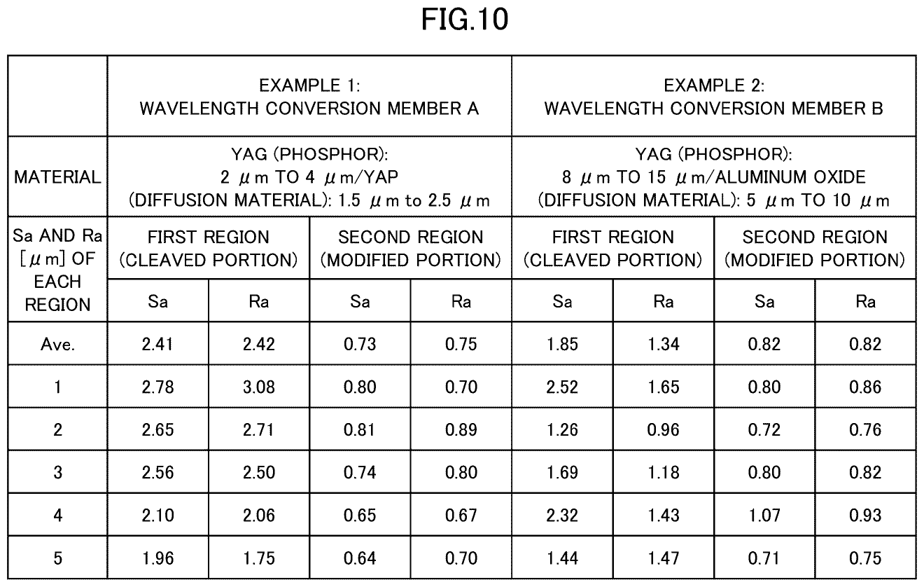

FIG. 10 illustrates the measurement results of Sa and Ra of the lateral surfaces of the wavelength conversion members. For the five samples of the wavelength conversion member A, the average value of Sa of first regions was 2.41 μm, the average value of Sa of second regions was 0.73 μm, the average value of Ra of the first regions was 2.42 μm, and the average value of Ra of the second regions was 0.75 μm. For the five samples of the wavelength conversion member B, the average value of Sa of first regions was 1.85 μm, the average value of Sa of second regions was 0.82 μm, the average value of Ra of the first regions was 1.34 μm, and the average value of Ra of the second regions was 0.82 μm.

From Examples 1 and 2, although the surface roughness of the first regions and the surface roughness of the second regions differ according to the types of the phosphors and the diffusion materials included in the wavelength conversion members, it was confirmed that the surface roughness of the first regions was greater than the surface roughness of the second regions. Accordingly, it is thought that, when a wavelength conversion member is used in a light emitting device or the like and is covered by a covering member such as a resin, the covering member being in contact with a first region of the wavelength conversion member allows for improving the adhesion between the covering member and the wavelength conversion member.

According to one embodiment of the present disclosure, a method of manufacturing an optical member having good adhesion to a covering member can be provided.

Although embodiments have been described in detail above, the above-described embodiments are non-limiting examples, and various modifications and substitutions can be made to the above-described embodiments without departing from the scope described in the claims.

What is claimed is:

1. A method of manufacturing an optical member, the method comprising:
providing a polycrystalline wavelength conversion member comprising phosphor particles and having a first surface and a second surface opposite to the first surface;
forming a modified portion inside the wavelength conversion member by focusing laser light inside the wavelength conversion member; and
cleaving the wavelength conversion member with the modified portion being a starting point, which comprises pressing the wavelength conversion member from a first surface side.

2. The method of manufacturing the optical member according to claim 1, wherein, in the step of cleaving the wavelength conversion member, a support member is disposed on the second surface of the wavelength conversion member, and the wavelength conversion member is pressed from the first surface side by a pressing member.

3. The method of manufacturing the optical member according to claim 2, wherein, in the step of cleaving the wavelength conversion member, the support member is elastically deformed by the pressing of the wavelength conversion member.

4. The method of manufacturing the optical member according to claim 1, wherein, in the step of forming the modified portion, the modified portion is formed at a position spaced apart from the first surface and the second surface.

5. The method of manufacturing the optical member according to claim 1, wherein, in the step of forming the modified portion, the modified portion is formed in a region having a depth of greater than 0 and 10 μm or less from the second surface of the wavelength conversion member.

6. The method of manufacturing the optical member according to claim 1, wherein a length of the modified portion in a depth direction of the wavelength conversion member is 2% or more and 30% or less of a thickness of the wavelength conversion member.

7. The method of manufacturing the optical member according to claim 1, wherein a width of the modified portion in a direction parallel to the second surface of the wavelength conversion member is 1 μm or more and 10 μm or less.

8. The method of manufacturing the optical member according to claim 1, wherein:
in the step of forming the modified portion, the modified portion is formed in a linear shape in a top view, and
in the step of cleaving the wavelength conversion member, the wavelength conversion member is pressed along the linear-shaped modified portion.

9. A light emitting device comprising:
a light emitting element;
an optical member disposed over the light emitting element and having a plate shape; and
a covering member covering lateral surfaces of the optical member and lateral surfaces of the light emitting element, wherein:
an upper surface of the optical member is exposed from the covering member,
the optical member is a polycrystalline wavelength conversion member comprising phosphor particles,
the optical member includes:
a first region where surfaces of phosphor particles are exposed and
a second region where cross sections of phosphor particles are exposed, and
the first region and the second region are located at different positions on a lateral surface of the wavelength conversion member in a height direction thereof.

10. The light emitting device according to claim 9, wherein a surface roughness of the first region is greater than a surface roughness of the second region.

11. The light emitting device according to claim 10, wherein
an arithmetic average surface roughness Ra of the first region is 2.0 μm or more and 3.0 μm or less, and
an arithmetic average surface roughness Ra of the second region is 0.5 μm or more and 1.0 μm or less.

12. The light emitting device according to claim 9, wherein the first region is provided over all of the lateral surfaces of the optical member along outer edges of a lower surface of the optical member.
